(19) United States
(12) Patent Application Publication
(10) Pub. No.: US 2025/0306067 A1
(43) Pub. Date: Oct. 2, 2025

(54) DELAY COMPENSATION

(71) Applicant: Jonathan Ephraim David Hurwitz, Edinburgh (GB)

(72) Inventor: Jonathan Ephraim David Hurwitz, Edinburgh (GB)

(21) Appl. No.: 19/078,089

(22) Filed: Mar. 12, 2025

(30) Foreign Application Priority Data
Mar. 26, 2024 (GB) 2404327.5

(51) Int. Cl. G01R 21/133; G01R 15/18

(52) U.S. Cl. CPC G01R 21/133; G01R 15/181

(57) ABSTRACT

This disclosure presents a system that can be used for improved accuracy energy measurements by compensating for delays in current and voltage channels. In one example, the system comprises a current measurement channel for measuring a current of a signal, the current measurement channel comprising an integrator for coupling to a di/dt sensor. In this example, the system also comprises a voltage measurement channel for measuring a voltage of the signal, the voltage measurement channel comprising a compensation filter configured to introduce a delay so as to at least partially compensate for a delay of the integrator in the current measurement channel.

### CLAIM OF PRIORITY

This patent application claims the benefit of priority of GB Patent Application Number 2404327.5, which was filed on Mar. 26, 2024, which is incorporated by reference herein in its entirety.

### BACKGROUND

Di/dt sensors like Rogowski coils have a response proportional to frequency. Their output it typically integrated to get a response largely flat with frequency over the frequency band of interest (for measurement of AC mains signals, the frequency band of interest can be from below the fundamental frequency of the AC mains, e.g. 50/60 Hz, to 10's kHz or beyond depending on interest in harmonics). As a result, it is possible to measure current across the frequency band of interest.

Integration can be done with an analog or digital integrator. An analog integrator can be formed by a low pass filter (LPF) having a corner frequency, or pole, below the fundamental frequency. The lower the pole of this LPF relative to the fundamental frequency of the AC mains, the lower the artifacts of the pole regarding magnitude and signal delay in the frequency band of interest. The lower the frequency of the analog pole, the larger the values needed for the analog components, which makes the components more expensive if they need to have good characteristics with temperature and lifetime (e.g. COG capacitor values). Energy measurement needs to be accurate when there are harmonics, or when there are different power factors or there are different frequencies. Accuracy of energy measurement may be affected by any delay in the current measurement signal introduced by the integrator, since this may cause a mismatch between the current and voltage measurements used to determine energy. As a result, it is desirable to minimise the delay effects of the integrator.

### SUMMARY

This disclosure presents a system that can be used for improved accuracy energy measurements by compensating for delays in current and voltage channels. In one example, the system includes a current measurement channel with an integrator coupled to a di/dt sensor and a voltage measurement channel with a compensation filter. The compensation filter introduces a delay to compensate for the integrator's delay across a range of frequencies, improving the accuracy of energy calculations. The system can be used in utility meters to measure energy or power more accurately. The compensation filter can be digital or analog and may be tunable to adjust its delay characteristics. This innovation enhances the precision of energy measurements, particularly when measuring signals that include harmonics.

In a first aspect of the disclosure, there is provided a system for measuring of a signal, the system comprising: a current measurement channel for measuring a current of the signal, the current measurement channel comprising an integrator for coupling to a di/dt sensor; and a voltage measurement channel for measuring a voltage of the signal, the voltage measurement channel comprising a compensation filter configured to introduce a delay so as to at least partially compensate for a delay of the integrator in the current measurement channel.

In a second aspect of the disclosure, there is provided a measurement system for measuring of a signal, the system comprising: a first measurement channel for measuring a first characteristic of the signal, wherein the first measurement channel comprises an integrator for coupling to a rate of change of first characteristic sensor; and a second measurement channel for measuring a second characteristic of the signal, the second measurement channel comprising a compensation filter configured to introduce a delay so as to at least partially compensate for a delay of the integrator of the first measurement channel.

In a third aspect of the disclosure, there is provided a utility meter for use in measuring energy of an electrical signal, the system: a rate of change sensor for positioning in proximity to an electrical conductor carrying the electrical signal; a first measurement channel for generating a measurement of a first characteristic of the electrical signal, wherein the first measurement channel comprises an integrator coupled to the rate of change sensor, and a second measurement channel for generating a measurement of a second characteristic of the signal, the second measurement channel comprising a compensation filter configured to introduce a delay so as to at least partially compensate for a delay of the integrator of the first measurement channel.

### DRAWINGS

Aspects of the present disclosure are described, by way of example only, with reference to the following drawings, in which:

FIG. 1A shows an example system in accordance with an aspect of the present disclosure;

FIG. 1B shows example frequency responses of the integrator and compensation filter of the system of FIG. 1A

FIG. 2 shows example details of the system of FIG. 1A;

FIG. 3 shows a further example system in accordance with an aspect of the present disclosure;

FIG. 4 shows alternative example details of the system of FIG. 1A;

FIG. 5 shows a further example system in accordance with an aspect of the present disclosure; and

FIG. 6 shows an example utility meter in accordance with the present disclosure.

### DETAILED DESCRIPTIONS

A single pole analog integrator with a pole around 0.5 Hz (achieved using the largest reasonably priced 0603 COG capacitor) with a reasonable 7MΩ resistor, has a signal delay described by:

$$tan {h}^{- 1} ( {F}_{f} / {F}_{c} ) / 360 * 1 / {F}_{f} at {F}_{f}$$

where F_{f} is the fundamental frequency of the signal being measured and F_{c} is the pole, or corner frequency, of the analog integrator.

If the integrator is configured to have a pole, F_{c}, at 0.54 Hz, and the fundamental frequency of the signal being measured, F_{f}, is 60 Hz the signal delay will be about 26 μs.

The signal delay for other types of analog integrator, for example having more than one pole, such as a trapezoidal integrator, may be described using different formulas.

For energy/power measurement of an AC mains signal (also sometimes referred to as an “AC utility signal” or “AC power signal”, the fundamental frequency of which is typically around 50 Hz or 60 Hz, both current measurement and a corresponding voltage measurement are required. The inventors have realised that differences in group delays between the current and voltage channels may decrease the accuracy of energy/power measurement. The inventors have recognised that one way to reduce the difference in group delay in order to achieve improved energy/power calculation is to add a fixed delay to the voltage measurement channel. In the example given above, a delay of 26 μs could be added to the voltage channel to match the delay of the integrator in the current channel. However, that amount of delay is experienced specifically by the fundamental frequency component of the current being measured. The delay experienced by other frequency components in the measured current, such as harmonics, will be different. Consequently, applying a fixed delay to the voltage channel in order to compensate for the delay experienced at the fundamental frequency may result in an error at other frequencies. For example, at the second harmonic (such as 20 kHz), the current channel delay caused by the integrator is about 6.5 μs, and at the 3^{rd} harmonic, the current channel delay caused by the integrator is about 2.9 μs. Consequently, a fixed voltage channel delay of 26 μs will result in −19.5 μs and −23.1 μs respective errors between the voltage and current measurement channels for the 2^{nd} and 3^{rd} harmonics.

Also, if the fundamental frequency F_{c} of the measured signal changes, for example by 2% to 58.8 Hz, the delay caused by the integrator in the current measurement channel becomes about 27 μs. If a delay of 26 μs has been added to the voltage channel, there will be a group delay difference of about 1 μs between the voltage and current measurement channels. With a power factor (PF) of 0.5, this results in an approximately 0.03% energy measurement error.

This disclosure seeks to address these problems, thereby improving the accuracy of energy calculations, by using a compensation filter to compensate the variable delay associated with the analog integrator across a range of frequencies.

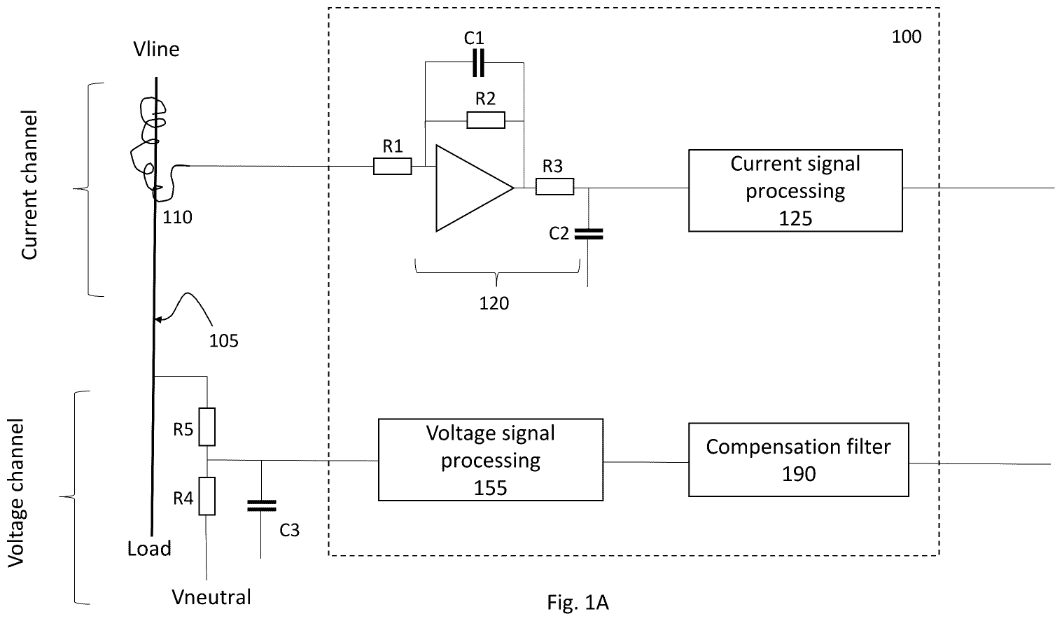

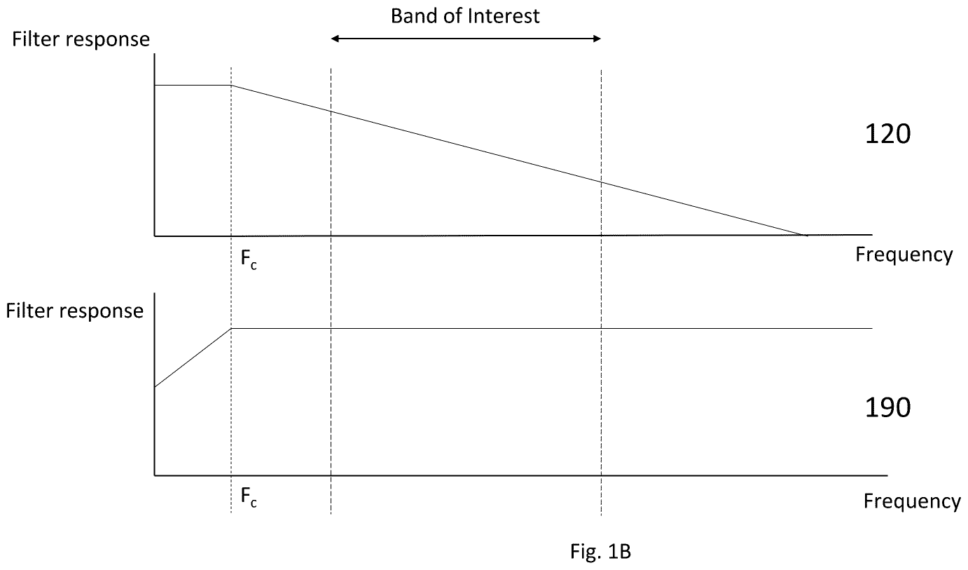

FIG. 1A shows an example measurement system 100 in accordance with an aspect of the present disclosure, to address the above problems. The represented system 100 is suitable for use in measuring an electrical signal, specifically measuring the current and voltage of a signal. The system 100 comprises a current channel for use in measuring the current of a signal carried by the electrical conductor 105 and a voltage channel for use in measuring the voltage of the signal carried by the electrical conductor 105. In this example, a line or mains voltage Vline is supplying a current and voltage to a load, for example a domestic or industrial electrical consumption load, and the system 100 can be used to measure that supplied current and voltage. The consumed electrical energy and/or power can ultimately be determined using the current and voltage measurements. It will be appreciated that the system 100 can also be used to measure a signal supplied by from a domestic or industrial generator, such as a domestic solar array, to the mains or line voltage supply.

The current channel comprises a dI/dt sensor 110 (such as a Rogowski Coil) for measuring the current of the signal. As the skilled person will appreciate, the dI/dt sensor 110 is suitable for positioning in proximity to the electrical conductor 105 (for example, partially or wholly surrounding the electrical conductor 105) so that a change in the current of the signal induces a response in the dI/dt sensor 110. The current channel of the system 100 comprises an analog integrator 120 configured to integrate the signal output by the dI/dt sensor 110 and output a signal having a largely flat response with respect to frequency across the frequency band of interest. The analog integrator 120 represented in FIG. 1A is merely one example implementation of an analog integrator and the skilled person will readily appreciate it may be implemented in various other ways. One terminal of the capacitor C2 is coupled to the resistor R2 and the other terminal of C2 may be coupled to any suitable reference, such as ground or Vneutral. In one non-limiting example, some of the values of the analog integrator 120 may be: C1=39 nF+/−5%; C2=2.2 nF (+/−1%); R2=7MΩ (+/−0.5%); R3=1 kΩ (+/−1%). In this example, the analog integrator 120 low pass filter (LPF) pole is about 0.5 Hz. It will be appreciated that this is merely one example implementation of an analog integrator and that any other design/implementation may alternatively be used.

The current channel also optionally includes a current signal processing circuit/unit 125, some examples of which are described later.

The voltage channel optionally includes a potential divider formed by R4 and R5 (which could be formed in any other suitable, alternative way, such as using capacitors) in order to reduce the magnitude of the voltage signal (Vline−Vneutral) to a better range for a voltage signal processing module/unit 155 (examples of which are described later) of the system 100. The voltage channel also optionally comprises a capacitor C3, for providing an anti-aliasing function. In order to address the earlier identified problems, the inventor has also included in the voltage channel a compensation filter 190, which is described in more detail later.

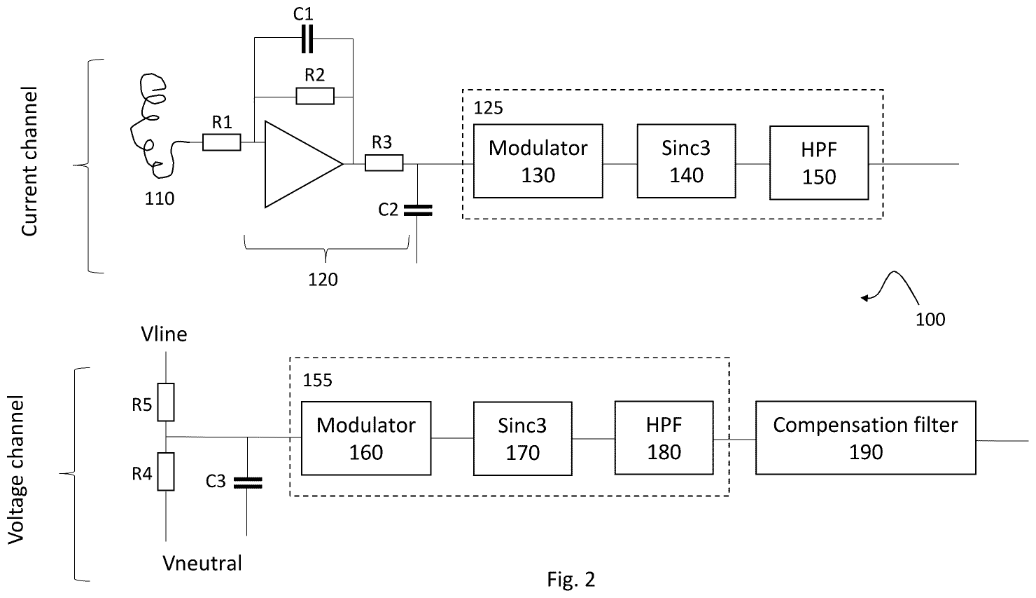

FIG. 2 shows an example implementation of the current signal processing circuit 125 and the voltage signal processing circuit 155. The current signal processing circuit 125 may comprise any one or more of: a modulator 130 (e.g., an analog to digital converter, ADC); a digital sinc3 filter 140; and/or a digital high pass filter (HPF) 150. The voltage signal processing circuit 155 may comprise any one or more of: a modulator 160 (e.g., an analog to digital converter, ADC); a digital sinc3 filter 170; and/or a digital high pass filter (HPF) 180. Each of these circuits/units will be very familiar to the skilled person and will therefore not be described further herein.

The compensation filter 190 may in one example be an infinite impulse response (IIR) HPF filter with a single nominal pole that is substantially the same as that of the analog integrator 120. However, it may alternatively be any other type of HPF or all-pass filter having the characteristics described below.

For the example integrator 120 configuration described earlier, the HPF may be configured to have a pole at around 0.5 Hz, to match that of the analog integrator 120. The compensation filter 190 is configured to mimic the analog integrator 120 delay characteristics across a range of signal frequencies that span at least part of the frequency band of interest, such that the overall group delay of the voltage channel substantially matches that of the current channel (for example, the group delays of the two channels are within 1 uS of each other across the range of signal frequencies, such as for all signal frequencies above 40 Hz). As a result, as the delay of the analog integrator 120 changes with changes in signal frequency, the delay of the compensation filter 190 should substantially track those changes across the range of frequencies such that overall group delay of the current channel should substantially match the overall group delay of the voltage channel. Consequently, accuracy of energy/power measurement should be improved across the range of frequencies.

To explain some of the terminology above, the frequency band of interest is the band or range of signal frequencies that are intended to be measured. For example, the frequency band of interest may include the fundamental frequency and one or more harmonics of the signal to be measured. In the example of a mains or utility signal having a fundamental frequency of 50 Hz or 60 Hz, the frequency band of interest may be 0.5 Hz to 40 kHz, or 2 Hz to 30 kHz, or 1 Hz to 100 kHz, etc. The range of signal frequencies for which the compensation filter 190 is configured to mimic the analog integrator 120 delay characteristics may be the same as the frequency band of interest, or may be different. If it is different, the range of signal frequencies should at least partially overlap the frequency band of interest, for example being fully encompassed by the frequency band of interest, or having a part of the range of signal frequencies within the frequency band of interest with the rest of the range of signal frequencies outside the frequency band of interest. For example, if the frequency band of interest is 0.5 Hz to 40 kHz, the range of signal frequencies may be all frequencies above 40 Hz, or frequencies between 30 Hz to 80 kHz, or 20 Hz to 30 kHz, or 0.1 Hz to 50 kHz, or 0.1 Hz to 25 kHz, etc. Regardless of the chosen range of signal frequencies, the compensation filter 190 should reduce or eliminate group delay differences between the current and voltage channels across at least part of the frequency band of interest, which may improve the accuracy of energy/power measurements obtained using the current and voltage measurements.

The compensation filter 190 may be programmable or tuneable so that its delay characteristics are adjustable. This may be used, for example, to change the delay compensation that it provides, for example by moving the pole of the compensation filter 190. This may enable the compensation filter 190 to tuned so as to adjust its pole to substantially match the pole of the analog integrator 120, or at least to reduce or minimise the difference between the two poles. The pole of the analog integrator 120 may optionally be determined based on measurements of the analog integrator 120. The skilled person will readily appreciate how such adjustments may be made in a digital HPF or all-pass filter, or an analog HPF or all-pass filter (for example by changing the component values, such as using variable capacitors and/or resistors, of the compensation filter). Such adjustments may be made in view of changes in the analog integrator 120 and/or changes in digital sampling rate that affect the group delay of the current channel. Additionally, the compensation filter 190 may be adjusted to compensate for differences in the group delay of the current channel and voltage channel caused by changes in the voltage channel, for example changes in the signal delay caused by other component/circuits in the voltage channel, such as an anti-aliasing filter.

FIG. 1B shows example frequency responses of the integrator 120 and the compensation filter 190. In this example, it can be seen that the pole, or corner frequency, Fc, of the two filters is set to be the same. Because the compensation filter has its pole below the frequency range of interest, it should not substantially or significantly affect the amplitude voltage signal passing through the voltage channel (i.e., it should only affect the phase/delay of the signal), thereby maintaining accuracy of voltage measurement. Since the pole of the compensation filter 190 is similar to, or the same as, that of the integrator 120, its delay/phase characteristics should also be the same or similar. As a result, within at least part of the frequency band of interest, the delay characteristics of the filters should be similar or the same, such that the delay of the integrator 120 is at least partially compensated for by the compensation filter 190.

It should be appreciated that in some particular implementations, the components and circuits of FIG. 1A may be standard components and circuits for energy/power measurement, with the exception of the compensation filter 190. Therefore, it may be possible to retrofit the compensation filter 190 into existing energy/power measurement systems, thereby improving accuracy of measurement of existing systems at relatively low cost.

Each of the current and voltage channels may further comprise any one or more of: an HPF, a decimator, an equaliser and/or any other type of signal processing unit/circuit.

Ideally the compensation filter 190 will introduce a delay that perfectly compensates for the group delay of the analog integrator 120, such that there is no difference between the group delay of the current channel and the group delay of the voltage channel across the range of signal frequencies for which the compensation filter 190 is configured to mimic the analog integrator 120 delay characteristics. However, this is not essential and any amount of compensation that reduces the difference in group delay between the two channels should improve the accuracy of energy/power measurement.

The compensation filter 190 may be a high pass filter, or an all pass filter, or a filter somewhere between a high pass and all pass filter. In all of these examples, the pole of the compensation filter 190 may be set to be below the frequency band of interest, so that the amplitude of the voltage measurement signal is not affected by the compensation filter 190, meaning that the voltage can still be measured accurately.

The analog integrator 120 may optionally be trimmable, or partially trimmable, so as to bring the analog integrator 120 delay to within an acceptable range of the compensation filter 190 delay (for example by adjusting one or more components of the analog integrator 120, such as by using one or more variable capacitors and/or resistors). This may be useful, for example, in the event that the compensation filter 190 cannot be trimmed or adjusted.

In one example implementation, the HPFs 150 and 180 may be of the same design, such that they have the same frequency characteristic. However, in another example implementation, they may be different (for example, having different poles) such that there is a delta/difference between their delay characteristics. In this situation, the difference in HPF delay characteristics may further contribute to the difference in group delay between the voltage and current channels in the frequency band of interest. In this case, the compensation filter 190 may be configured also to compensate for the delay difference between HPF 150 and HPF 190, in addition to the delay introduced by the analog integrator 120. Consequently, it should be understood that the compensation filter 190 may be configured so as to reduce or eliminate any difference between the group delay of the voltage channel (the group delay of voltage signal processing circuit 155 and the compensation filter 190) and the group delay of the current channel (the analog filter 120 and the current signal processing circuit 125).

The circuit/functional block ordering of FIGS. 1 and 2 is one particular example, and in an alternative the ordering may be changed. Furthermore, at least some of the circuits/functional blocks may be implemented in either the analog or digital domain.

For example, in FIGS. 1 and 2, the compensation filter 190 is a digital filter positioned at the output of the voltage signal processing circuit 155. In an alternative, it may be positioned anywhere downstream of the modulator 160, for example between the modulator 160 and sinc filter 170, or between the sinc filter 170 and HPF 180.

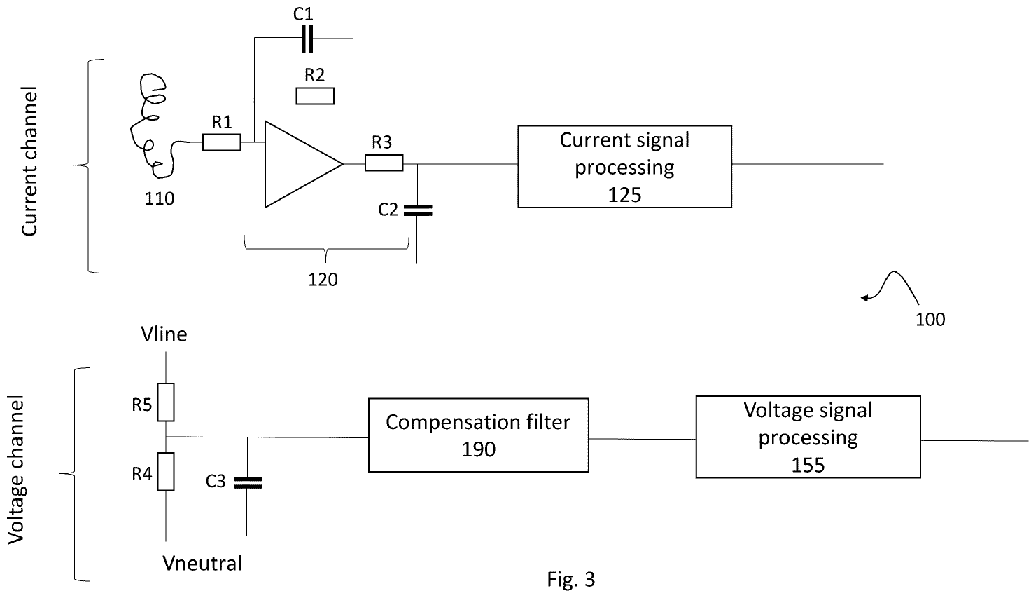

FIG. 3 shows a further example implementation where the compensation filter 190 is an analog filter. Consequently, it may be positioned anywhere within the analog part of the voltage channel, which in this example means that it precedes the voltage signal processing circuit 155 since the modulator 160 is the first block within the current signal processing unit 155 (although it could alternatively be anywhere else within the analog part of the channel).

Furthermore, in the examples of FIGS. 1 to 3, all of the blocks within the current signal processing unit 125 and voltage signal processing unit 155 are digital blocks (other than the modulators 130 and 160). However, any one or more of the blocks of the current signal processing unit 125 and/or voltage signal processing unit 155 may alternatively be analog units/modules.

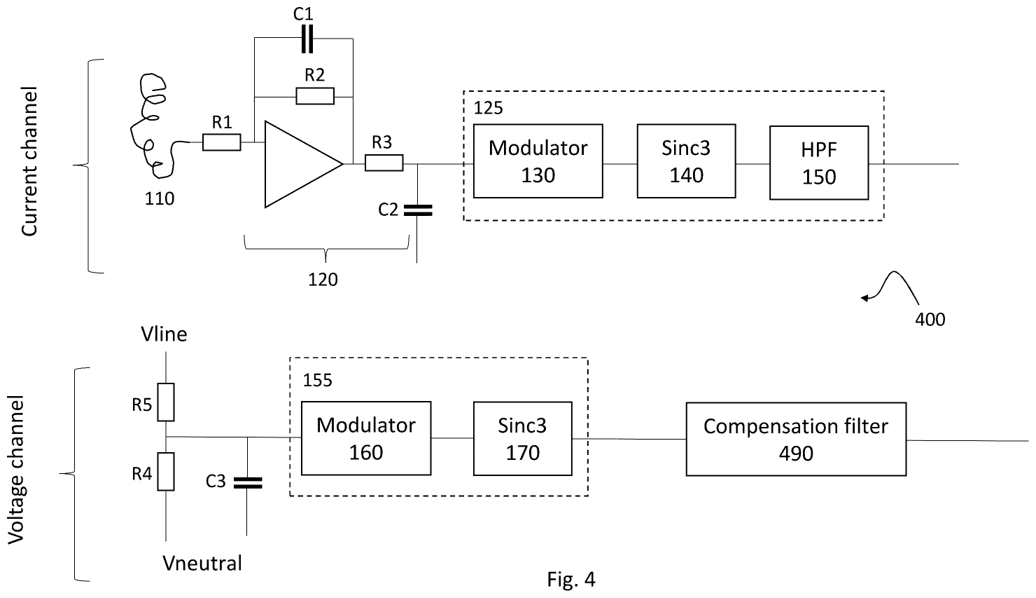

FIG. 4 shows a further example system 400 that is the same as the system 100, except the HPF 180 and compensation filter 190 have been replaced by a single compensation filter 490 configured to perform the functionality of both the HPF 180 and compensation filter 190. The compensation filter 490 may be positioned anywhere in the voltage channel and may be a digital filter or analog filter.

In each of the examples of FIGS. 1 to 4, the current and voltage channels are configured to process single ended signals. However, the current and/or voltage channel may alternatively be configured to handle differential signals. For example, the dI/dt sensor 110 may be a differential sensor and the current channel may be configured accordingly to process differential signals.

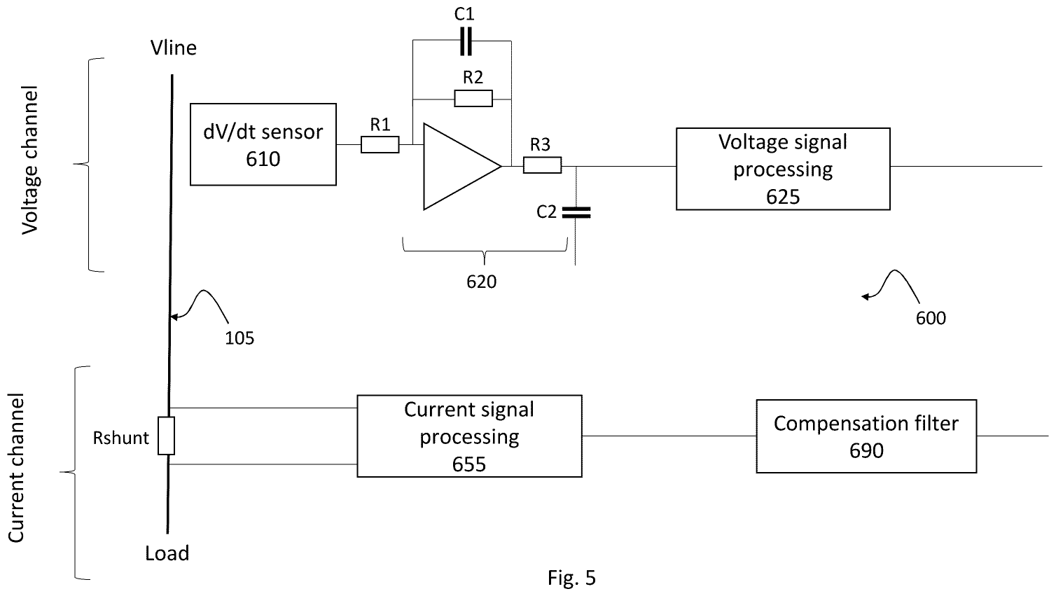

FIG. 5 shows a system 600 in accordance with a further aspect of the disclosure. System 600 is similar to systems 100 and 400 above, but the voltage channel is configured for measuring the voltage of the electrical conductor 105 using a rate of change of voltage (dV/dt) sensor 610. The dV/dt sensor 610 may take any suitable form, for example a non-contact capacitive voltage sensor, and may be positioned in proximity to an electrical conductor carrying the signal that is to be measured (for example, positioned to partially or fully surround the electrical conductor 105). The voltage channel comprises an integrator 620 for the same purpose as the integrator 120, and a voltage signal processing module/unit 625, which may be the same as any of the example voltage signal processing units 155 described above.

The current channel comprises a current sensor, which in this example is a shunt resistor Rshunt although it may be any suitable type of current sensor, that is configured for measuring the current carried in the electrical conductor 105. For example, it may be any other type of sensor that generates a signal that is proportional, or substantially or nominally proportional, to current, such as a current transformer (CT), a Hall sensor, etc. The current channel further comprises a current signal processing module/unit 655, which may be the same as any of the example current signal processing units 125 described above. The current channel further comprises a compensation filter 690, which is configured to perform the same function as the compensation filter 190 described above i.e., at least partially compensate the delay of the integrator 620. As with the compensation filter 190, the compensation filter 690 may be positioned anywhere in the current channel and may be a digital or analog filter. Furthermore, it may optionally be tunable, for example so that its pole may be adjusted based on the pole of the integrator 620 (for example, so that the compensation filter pole is the same, or similar, to the integrator pole).

Optionally, rate of change sensors may be used for measuring both the current and voltage. In this case, both the current and voltage channels may comprise an integrator. In such an example, one or both channels may comprise a compensation filter, configured to at least partially compensate (e.g., reduce or eliminate) any difference in group delay between the two channels, for example caused by different delays between the two integrators.

Thus, it can be seen that according to the present disclosure, the system may comprise a first channel having a rate of change sensor and integrator for use in measuring a first characteristic of an electrical signal, and comprise a second channel for use in measuring a second characteristic of the electrical signal, wherein the second channel comprises a compensation filter for at least partially compensating the delay of the integrator. The first signal characteristic may be current and the second signal characteristic may be voltage, or the first signal characteristic may be voltage and the second signal characteristic may be current.

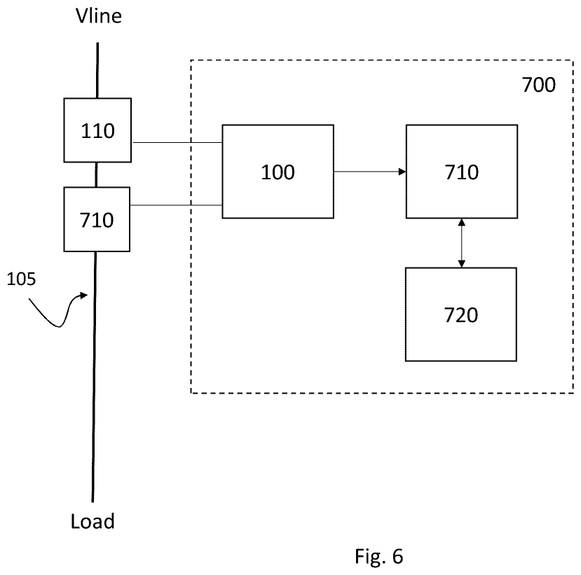

FIG. 6 shows an example utility meter 700 in accordance with an aspect of this disclosure. The utility meter 700 is configured to measure the energy (or, analogously, the power) of the signal carried in the electrical conductor 105. For this purpose, the utility meter 700 comprises the measurement system 100 (or the measurement system 400) suitable for coupling to the dI/dt current sensor 110 and an optional voltage sensing arrangement 710 (such as the potential divider of FIG. 1A), although the measurement system 100 may be coupled to the electrical conductor 105 in any suitable way for measuring the voltage associated with the electrical conductor 105. In an alternative, the utility meter 700 may itself comprise the dI/dt current sensor 110 and/or optional voltage sensing arrangement 710.

The measurement system 100 is configured to generate measurements of the current carried in the electrical conductor 105 and the voltage of the electrical conductor 105. The utility meter 700 is further configured to determine a measurement of energy (or analogously power) of the electrical signal carried by the electrical conductor 105 based on the measurement of current and the measurement of voltage (e.g., P=V.I, or E=V.I.t). In this example, the utility meter 700 comprises a processor 710, such as a microprocessor or microcontroller, configured to receive the measurements of voltage and current and generate the measure of energy (and/or power). However, the utility meter 700 may be configured to generate a measure of energy (and/or power) in any other suitable way, such as by using dedicated logic or circuits. The utility meter 700 may optionally comprise memory 720, such as volatile or non-volatile memory, for storing computer program instructions for execution by the processor 710 and/or for storing one or more measurements of voltage, current, energy and/or power. Optionally, the utility meter 700 is further configured to output the generated measurement of energy (and/or power), for example visually using a built-in display and/or via one or more suitable communications channels, such as Bluetooth, Wi-Fi, cellular network, etc.

Whilst in this example current is configured to be measured using a dI/dt sensor 110, it will be appreciated that the utility meter 700 may alternatively comprise the measurement system 600, wherein a dV/dt sensor 610 is used for measuring the voltage and a different type of current sensor, such as a shunt, is used for measuring the current (or a rate of change sensor, dI/dt, is also used for measuring the current).

The skilled person will readily appreciate that various alterations or modifications may be made to the above described aspects of the disclosure without departing from the scope of the disclosure.

For example, the aspects of the disclosure are typically described in the context of wanting to measure the energy and/or power of a signal, particularly for the purpose of utility metering. However, this disclosure is relevant for any purpose and/or situation in which measurements of the voltage and current of a signal are desired.

The terminology “coupled” used above encompasses both a direct electrical connection between two components, and an indirect electrical connection where the two components are electrically connected to each other via one or more intermediate components. Therefore, it should be understood that units/modules/components/circuits shown in the figures as being coupled together directly or indirectly connected to each other.

### ASPECTS OF THE DISCLOSURE

Non-limiting aspects of the disclosure are set out in the following numbered clauses.

### First Set of Numbered Aspects

1. An energy/power measurement system comprising:
a current measurement channel comprising an integrator for coupling to a di/dt sensor; and
a voltage measurement channel comprising a filter configured to introduce a delay so as to at least partially compensate for a group delay of the integrator in the current measurement channel.
   2. The system of clause 1, wherein the digital filter is configured to introduce a delay so as to at least partially compensate for a delay of the integrator in the current measurement channel across a range of signal frequencies.
   3. The system of clause 2, wherein the range of signal frequencies spans at least part of the frequency range of interest for the energy/power measurement system.
   4. The system of clause 3, wherein the range of the signal frequencies spans the entire frequency range of interest for the energy/power measurement system, or spans some, but not all, of the frequency range of interest for the energy/power measurement system.
   5. The system of any preceding clause, wherein the current measurement channel further comprises at least one of: a high pass filter, a decimator, an equaliser.
   6. The system of any preceding clause, wherein the voltage measurement channel further comprises at least one of: a high pass filter, a decimator, an equaliser.
   7. The system of any preceding clause, wherein the filter comprises a high pass filter and/or an all pass filter.
   8. The system of any preceding clause, wherein the filter is a digital filter.
   9. The system of any preceding clause, wherein the filter is tuneable.
   10. The system of any preceding clause, wherein the integrator is an analog integrator.
   11. The system of any preceding clause, wherein the integrator is trimmable.
   12. The system of any preceding clause, wherein a pole of the filter is configured to substantially match a pole of the integrator.

### Second Set of Numbered Aspects

1. A system for measuring of a signal, the system comprising:
a current measurement channel for measuring a current of the signal, the current measurement channel comprising an integrator for coupling to a di/dt sensor; and
a voltage measurement channel for measuring a voltage of the signal, the voltage measurement channel comprising a compensation filter configured to introduce a delay so as to at least partially compensate for a delay of the integrator in the current measurement channel.
   2. The system of clause 1, wherein the delay introduced by the compensation filter is configured to at least partially compensate for the delay of the integrator in the current measurement channel across a range of frequencies of the signal.
   3. The system of clause 2, wherein the range of frequencies of the signal spans at least part of the frequency band of interest for the measurement system.
   4. The system of clause 3, wherein the range of the frequencies of the signal spans the entire frequency band of interest for measurement system, or spans some, but not all, of the frequency band of interest for the measurement system.
   5. The system of any preceding clause, wherein the current measurement channel further comprises at least one of: a high pass filter, a decimator, an equaliser.
   6. The system of any preceding clause, wherein the voltage measurement channel further comprises at least one of: a high pass filter, a decimator, an equaliser.
   7. The system of any preceding clause, wherein the compensation filter comprises a high pass filter or an all pass filter.
   8. The system of any preceding clause, wherein the compensation filter is a digital filter.
   9. The system of any preceding clause, wherein the compensation filter is tuneable.
   10. The system of any preceding clause, wherein the integrator is an analog integrator.
   11. The system of any preceding clause, wherein the integrator is trimmable.
   12. The system of any preceding clause, wherein a pole of the compensation filter is configured to substantially match a pole of the integrator.
   13. The system of any preceding clause, wherein the current channel further comprises a first filter having a first delay, and
wherein the voltage channel further comprises a second filter having a second delay, and
wherein compensation filter configured to introduce a delay so as to at least partially compensate for the delay of the integrator in the current measurement channel and for a difference between the first delay and the second delay.
   14. The system of any preceding clause, further configured to measure an energy or power of the signal based on a measurement of the current of the signal and a measurement of the voltage of the signal.
   15. The system of any preceding clause, wherein the rate of change of current sensor is a Rogowski coil.
   16. A measurement system for measuring of a signal, the system comprising:
a first measurement channel for measuring a first characteristic of the signal, wherein the first measurement channel comprises an integrator for coupling to a rate of change of first characteristic sensor; and
a second measurement channel for measuring a second characteristic of the signal, the second measurement channel comprising a compensation filter configured to introduce a delay so as to at least partially compensate for a delay of the integrator of the first measurement channel.
   17. The measurement system of clause 16, wherein the first characteristic of the signal is a current of the signal, and
wherein the rate of change of first characteristic sensor is a rate of change of current sensor, and
wherein the second characteristic of the signal is a voltage of the signal.
   18. The measurement system of clause 16, wherein the first characteristic of the signal is a voltage of the signal, and
wherein the rate of change of first characteristic sensor is a rate of change of voltage sensor, and
wherein the second characteristic of the signal is a current of the signal.
   19. A utility meter for use in measuring energy of an electrical signal, the system:
a rate of change sensor for positioning in proximity to an electrical conductor carrying the electrical signal;
a first measurement channel for generating a measurement of a first characteristic of the electrical signal, wherein the first measurement channel comprises an integrator coupled to the rate of change sensor, and
a second measurement channel for generating a measurement of a second characteristic of the signal, the second measurement channel comprising a compensation filter configured to introduce a delay so as to at least partially compensate for a delay of the integrator of the first measurement channel.
   20. The utility meter of clause 19, wherein the first characteristic of the signal is a current of the signal, and
wherein the second characteristic of the signal is a voltage of the signal, and
wherein the rate of change sensor is a dI/dt sensor.
   21. The utility meter of clause 19, wherein the first characteristic of the signal is a voltage of the signal, and
wherein the second characteristic of the signal is a current of the signal, and
wherein the rate of change sensor is a dV/dt sensor.
   22. The utility meter of any of claims 19-21, further configured to determine a measurement of energy of the electrical signal using the measurement of the first characteristic of the electrical signal and the measurement of the second characteristic of the electrical signal.

1. A system for measuring of a signal, the system comprising:
a current measurement channel for measuring a current of the signal, the current measurement channel comprising an integrator for coupling to a rate of change of current (di/dt) sensor; and
a voltage measurement channel for measuring a voltage of the signal, the voltage measurement channel comprising a compensation filter configured to introduce a delay so as to at least partially compensate for a delay of the integrator in the current measurement channel.

2. The system of claim 1, wherein the delay introduced by the compensation filter is configured to at least partially compensate for the delay of the integrator in the current measurement channel across a range of frequencies of the signal.

3. The system of claim 2, wherein the range of frequencies of the signal spans at least part of a frequency band of interest for the measurement system.

4. The system of claim 3, wherein the range of the frequencies of the signal spans an entirety of the frequency band of interest for measurement system, or spans some, but not all, of the frequency band of interest for the measurement system.

5. The system of claim 1, wherein the current measurement channel further comprises at least one of: a high pass filter, a decimator, an equaliser.

6. The system of claim 1, wherein the compensation filter comprises a high pass filter or an all pass filter.

7. The system of claim 1, wherein the compensation filter is a digital filter.

8. The system of claim 1, wherein the compensation filter is tuneable.

9. The system of claim 1, wherein the integrator is trimmable.

10. The system of claim 1, wherein a pole of the compensation filter is configured to substantially match a pole of the integrator.

11. The system of claim 1, wherein the current channel further comprises a first filter having a first delay, and
wherein the voltage channel further comprises a second filter having a second delay, and
wherein compensation filter configured to introduce a delay so as to at least partially compensate for the delay of the integrator in the current measurement channel and for a difference between the first delay and the second delay.

12. The system of claim 1, further configured to measure an energy or power of the signal based on a measurement of the current of the signal and a measurement of the voltage of the signal.

13. The system of claim 1, wherein the di/dt sensor is a Rogowski coil.

14. A measurement system for measuring of a signal, the system comprising:
a first measurement channel for measuring a first characteristic of the signal, wherein the first measurement channel comprises an integrator for coupling to a rate of change of first characteristic sensor; and
a second measurement channel for measuring a second characteristic of the signal, the second measurement channel comprising a compensation filter configured to introduce a delay so as to at least partially compensate for a delay of the integrator of the first measurement channel.

15. The measurement system of claim 14, wherein the first characteristic of the signal is a current of the signal, and
wherein the rate of change of first characteristic sensor is a rate of change of current sensor, and
wherein the second characteristic of the signal is a voltage of the signal.

16. The measurement system of claim 14, wherein the first characteristic of the signal is a voltage of the signal, and
wherein the rate of change of first characteristic sensor is a rate of change of voltage sensor, and
wherein the second characteristic of the signal is a current of the signal.

17. A utility meter for use in measuring energy of an electrical signal, the utility meter comprising:
a rate of change sensor for positioning in proximity to an electrical conductor carrying the electrical signal;
a first measurement channel for generating a measurement of a first characteristic of the electrical signal, wherein the first measurement channel comprises an integrator coupled to the rate of change sensor, and
a second measurement channel for generating a measurement of a second characteristic of the signal, the second measurement channel comprising a compensation filter configured to introduce a delay so as to at least partially compensate for a delay of the integrator of the first measurement channel.

18. The utility meter of claim 17, wherein the first characteristic of the signal is a current of the signal, and
wherein the second characteristic of the signal is a voltage of the signal, and
wherein the rate of change sensor is a dI/dt sensor.

19. The utility meter of claim 17, wherein the first characteristic of the signal is a voltage of the signal, and
wherein the second characteristic of the signal is a current of the signal, and
wherein the rate of change sensor is a dV/dt sensor.

20. The utility meter of claim 17, further configured to determine a measurement of energy of the electrical signal using the measurement of the first characteristic of the electrical signal and the measurement of the second characteristic of the electrical signal.
